(19) United States
(12) Patent Application Publication
(10) Pub. No.: US 2009/0047789 A1
(43) Pub. Date: Feb. 19, 2009

(54) METHOD FOR FABRICATING SEMICONDUCTOR DEVICE

(75) Inventor: Tae-Woo JUNG, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: HYNIX SEMICONDUCTOR INC., Ichon-shi (KR)

(21) Appl. No.: 12/164,068

(22) Filed: Jun. 29, 2008

(30) Foreign Application Priority Data
Aug. 13, 2007 (KR) 10-2007-0081183

(51) Int. Cl. H01L 21/027

(52) U.S. Cl. 438/694; 257/E21.023

(57) ABSTRACT

A method for fabricating a semiconductor device includes forming an amorphous carbon layer over a substrate, forming a hard mask pattern over the amorphous carbon layer, and etching the amorphous carbon layer with an etching gas including sulfur (S) using the hard mask pattern as an etch barrier. Deformation of the amorphous carbon patterns is prevented by hardening the sidewalls of the amorphous carbon layer exposed during etching of the amorphous carbon layer. Therefore, when the etch target layer is etched with the amorphous carbon patterns having a vertical shape, pattern uniformity of the etch target pattern can be improved.

### CROSS-REFERENCE TO RELATED APPLICATIONS

The present invention claims priority of Korean patent application number 10-2007-0081183 filed on Aug. 13, 2007, which is incorporated by reference in its entirety.

### BACKGROUND OF THE INVENTION

The present invention relates to a method for fabricating a semiconductor device, and more particularly, to a method for etching an amorphous carbon layer used as a hard mask layer in a semiconductor device. The present invention further relates to a method for fabricating a semiconductor device in order to prevent deformation of an amorphous carbon pattern by hardening sides of the amorphous carbon pattern.

In accordance with the high integration of a semiconductor device, a thickness of a photoresist pattern during a mask process should be decreased and, thus, it is difficult to etch an etch target layer merely using the photoresist pattern. To overcome this limitation, it is suggested that a hard mask layer is formed under the photoresist pattern. An amorphous carbon layer is often used as the hard mask layer.

It is difficult to fabricate a semiconductor device with a photoresist pattern formed by a single exposure process in accordance with shrinkage of a minimum pitch of a semiconductor device pattern. Thus, a method for forming a micro pattern such as a double exposure etching technology is suggested.

However, when an amorphous carbon layer is used as a hard mask layer with the method for forming the micro pattern as described above, limitations exist which will be described hereinafter.

FIGS. 1A to 1C show limitations of a typical amorphous carbon pattern.

First, when the amorphous carbon layer is etched by a mixed gas of nitrogen (N₂) and oxygen (O₂), a line width of an etched portion of the amorphous carbon layer may be smaller than a target line width. Therefore, the etched amorphous carbon layer may be difficult to use as the hard mask layer during etching of the etch target layer. That is, referring to FIG. 1A, an etched amorphous carbon layer 11 has a profile having a saw-tooth shape 12 due to a notched line width of the etched amorphous carbon layer.

Second, when the amorphous carbon layer is etched by a mixed gas of N₂ and hydrogen (H₂), a large amount of polymer may be generated. Furthermore, when the polymer is re-deposited on an etched portion of the amorphous carbon layer, a space between neighboring amorphous carbon patterns 21 may be filled with the polymer as shown in FIG. 1B by reference number 22.

Thirdly, when the amorphous carbon layer is etched by a mixed gas of O₂, N₂ and methane (CH₄), shapes of etched amorphous carbon patterns 31 are not uniform as shown in FIG. 1C. Furthermore, since a polymer that occurs during etching of the amorphous carbon layer may be re-deposited on an etched portion of the amorphous carbon patterns 31, a line width of the amorphous carbon pattern may be decreased. Thus, a method to overcome the above described limitations is required.

### SUMMARY OF THE INVENTION

Embodiments of the present invention are directed to provide a method for fabricating a semiconductor device, which can prevent deformation of an amorphous carbon pattern by hardening sides of the amorphous carbon pattern.

In accordance with an aspect of the present invention, a method for fabricating a semiconductor device is provided. The method includes forming an amorphous carbon layer over a substrate, forming a hard mask pattern over the amorphous carbon layer, and etching the amorphous carbon layer with an etching gas including sulfur (S) using the hard mask pattern as an etch barrier.

In accordance with another aspect of the present invention, a method for fabricating a semiconductor device is provided. The method includes forming an amorphous carbon layer over a substrate, forming a hard mask pattern over the amorphous carbon layer, and etching the amorphous carbon layer with an etching gas using the hard mask pattern as an etch barrier, wherein the amorphous carbon layer is etched while simultaneously forming a sidewall protection layer on sidewalls of the amorphous carbon layer exposed by the etching.

### BRIEF DESCRIPTION OF THE DRAWINGS

FIG. 1A illustrates a micrographic view of deformation of amorphous carbon patterns having a saw-tooth shape.

FIG. 1B illustrates a micrographic view of amorphous carbon patterns adhering to neighboring amorphous carbon patterns.

FIG. 1C illustrates a micrographic view of amorphous carbon patterns having a poor etching profile and a line width smaller than a target width.

FIGS. 2A to 2C illustrate cross-sectional views showing a method for fabricating a semiconductor device in accordance with an embodiment of the present invention.

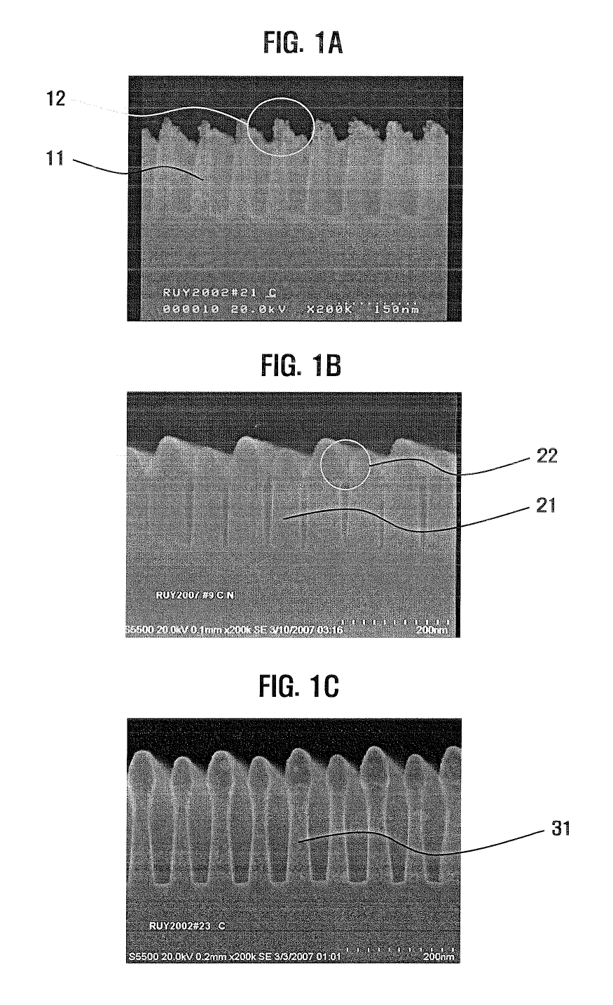

### DESCRIPTION OF SPECIFIC EMBODIMENTS

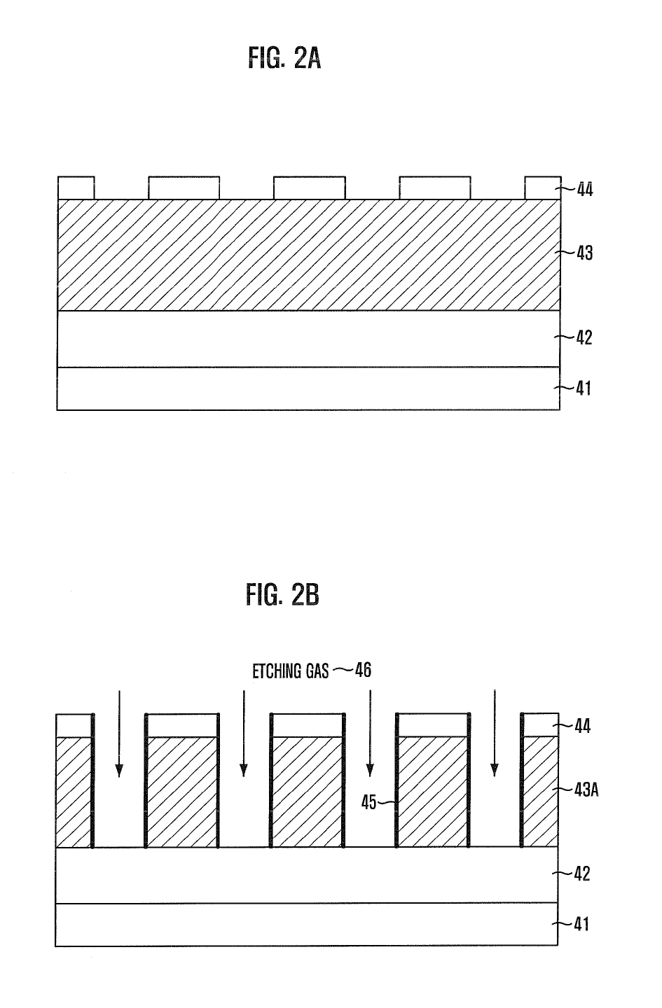

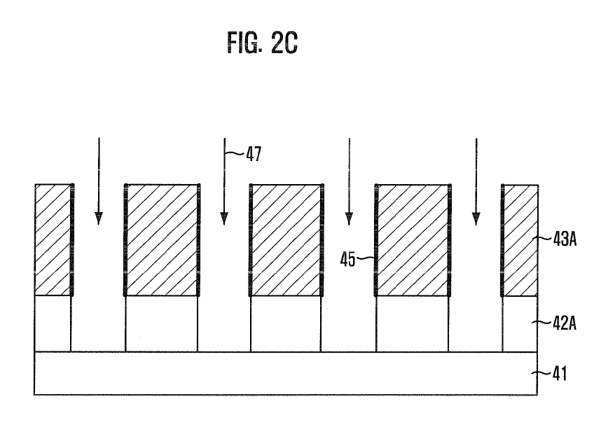

FIGS. 2A to 2C illustrate cross-sectional views showing a method for fabricating a semiconductor device in accordance with an embodiment of the present invention.

Referring to FIG. 2A, an etch target layer 42 is formed over a substrate 41, and then an amorphous carbon layer 43 and a hard mask pattern 44 are sequentially formed over the etch target layer 42. The hard mask pattern 44 includes a hard mask layer micro-patterned by a method for forming a micro pattern such as a double exposure etching technology. Furthermore, it is desirable that the hard mask pattern 44 is formed with silicon oxynitride (SiON) to improve an etch selectivity of the hard mask pattern 44 with respect to the amorphous carbon layer 43.

Referring to FIG. 2B, the amorphous carbon layer 43 is etched using the hard mask pattern 44 as an etch barrier. The etching of the amorphous carbon layer 43 is performed using an etching gas 46 including a sulfur (S) gas. The etching gas 46 including S may include a mixed gas of sulfur dioxide (SO₂) and carbon monoxide (CO), oxygen (O₂), a mixed gas of helium dioxide (HeO₂), nitrogen (N₂) or a combination thereof, or the etching gas 46 including S may include a mixed gas of sulfanylidenemethanone (COS) and CO, O₂, HeO₂, N₂ or a combination thereof. Specifically, the etching gas 46 including S may include a mixed gas of SO₂ and CO, a mixed gas of SO₂ and O₂, a mixed gas of SO₂ and HeO₂, a mixed gas of SO₂ and N₂, a mixed gas of COS and CO, a mixed gas of COS and O₂, a mixed gas of COS and HeO₂, a mixed gas of COS and N₂, and so on.

An argon (Ar) gas may additionally be added to the above described mixed gas, that is, the etching gas 46, in order to improve an etching rate of the amorphous carbon layer 43. The Ar gas increases the etching rate of the amorphous carbon layer 43 and easily etches a portion of an etch target region having a narrow space since the Ar has a large atomic weight.

Moreover, a hydrogen bromide (HBr) gas may also be added to the etching gas 46 to improve a line edge roughness (LEG) characteristic of an etched surface of the amorphous carbon layer 43. The HBr gas may be used as a gas for improving a roughness of the surface of the amorphous carbon layer 43.

The etching process for etching the amorphous carbon layer 43 is performed at a temperature of approximately 10° C. to approximately 60° C.; a pressure of approximately 1 mTorr to approximately 100 mTorr; and a ratio of a maximum power to a bias power ranging from approximately 0.5:1 to approximately 1.5:1 in a chamber.

Thus, when the amorphous carbon layer 43 is etched by using the etching gas 46 including S, carbon sulfide or carbonyl sulfide is formed over exposed sidewalls of the etched amorphous carbon pattern 43A. The carbon sulfide and the carbonyl sulfide may act as a thin layer for protecting the sidewalls of the amorphous carbon pattern 43A. The carbon sulfide and the carbonyl sulfide are referred to as a “sidewall protection layer” as denoted by reference numeral 45.

The sidewall protection layer 45 is a kind of a passivation layer formed by a reaction between a carbon (C) component in the amorphous carbon layer 43 and a S component in the etching gas 46. Furthermore, the sidewall protection layer 45 is harder than the amorphous carbon pattern 43A.

Carbon-hydroxide (CH) based gas having a large amount of carbon (C) and hydrogen (H) may be added to the above described etching gas 46 including S to improve the passivation characteristics of the sidewall protection layer 45. The CH based gas may include methane (CH₄) or acetylene (C₂H₄).

The CH-based gas can be absorbed on the surface of the amorphous carbon layer 43 since polymerization between the C and H in the CH-based gas may occur during etching of the amorphous carbon layer 43. Thus, the function of the sidewall protection layer 45 may be improved.

Furthermore, tetraclorosilane (SiCl₄) may additionally be added to the etching gas 46 including S to improve the passivation characteristics of the sidewalls protection layer 45. The passivation characteristics of the sidewalls protection layer 45 may be improved since the SiCl₄ gas includes silicon (Si).

Moreover, it is desirable that a flow rate of SO₂ or COS should be less than a flow rate of the gas that is COS, CO, O₂, HeO₂, N₂ or a combination. When the flow rate of SO₂ or COS is higher than the flow rate of the other gas, etching of the amorphous carbon layer 43 may be disturbed because the amorphous carbon layer 43 is over hardened. A portion of the etch target layer is intentionally etched by an over etching process while forming the amorphous carbon pattern 43A in order to easily etch the etch target layer 42 during a subsequent etching process for the etch target layer 42. It is desirable that a thickness of the etched portion of the etch target layer 42 ranges from approximately 5 Å to approximately 50 Å. The hard mask pattern 44 is then removed.

Referring to FIG. 2C, the etch target layer 42 is etched using the amorphous carbon pattern 43A with sidewall protection layer 45 as an etch barrier. Thus, etch target patterns 42A are formed without deformation after the etch process 47.

As described above, the embodiment of the present invention overcomes the deformation of the amorphous carbon patterns 43A by chemically hardening the sidewalls of the amorphous carbon patterns 43A. Furthermore, the method for hardening the sidewalls of the amorphous carbon patterns 43A uses the etching gas 46 including S.

The etching gas 46 including S may include a mixed gas of SO₂ and CO, O₂, HeO₂, N₂ or a combination thereof, or may include a mixed gas of COS and CO, O₂, HeO₂, N₂ or a combination thereof.

Deformation of the amorphous carbon patterns 43A during etching of the amorphous carbon layer 43 can be prevented since the sidewall protection layer 45 (i.e., the hardened layer) is formed on the sidewalls of the amorphous carbon patterns 43A while the amorphous carbon layer 43 is etched using the etching gas 46 including S. The sidewall protection layer 45 includes carbon sulfide or carbonyl sulfide.

Furthermore, the CH-based gas or SiCl4 gas can additionally be added to the etching gas 46 including S, and then the passivation characteristics of the sidewall protection layer 45 can be improved.

As a result, the amorphous carbon pattern 43A is formed without deformation and the etch target pattern 42A can also be obtained without deformation using the amorphous carbon pattern 43A without deformation in accordance with the embodiment of the present invention.

The present invention as described hereinbefore can prevent deformation of the amorphous carbon patterns by hardening the sidewalls of the amorphous carbon layer exposed during etching of the amorphous carbon layer. Therefore, when the etch target layer is etched with the amorphous carbon patterns having a vertical shape, pattern uniformity of the etch target pattern can be improved. That is, stability and reliability of semiconductor devices can be improved.

While the present invention has been described with respect to specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising;
forming an amorphous carbon layer over a substrate;
forming a hard mask pattern over the amorphous carbon layer; and
etching the amorphous carbon layer with an etching gas comprising sulfur (S) using the hard mask pattern as an etch barrier.

2. The method as recited in claim 1, wherein etching the amorphous carbon layer includes etching the amorphous carbon layer using the etching gas while simultaneously forming a sidewall protection layer on sidewalls of the amorphous carbon layer exposed by the etching.

3. The method as recited in claim 1, wherein the etching gas comprises a mixed gas of sulfur dioxide (SO₂) and one selected from the group consisting of carbon monoxide (CO), oxygen (O₂), helium dioxide (HeO₂), nitrogen (N₂) and a combination thereof.

4. The method as recited in claim 1, wherein the etching gas comprises a mixed gas of sulfanylidenemethanone (COS) and one selected from the group consisting of CO, O₂, HeO₂, N₂ and a combination thereof.

5. The method as recited in claim 1, wherein etching the amorphous carbon layer is performed by adding a carbon-hydroxide (CH) based gas or a tetraclorosilane (SiCl₄) gas to the etching gas.

6. The method as recited in claim 1, wherein etching the amorphous carbon layer is performed by adding an argon (Ar) gas to the etching gas.

7. The method as recited in claim 1, wherein etching the amorphous carbon layer is performed by adding a hydrogen bromide (HBr) gas to the etching gas.

8. The method as recited in claim 2, wherein the sidewall protection layer includes carbon sulfide or carbonyl sulfide.

9. The method as recited in claim 1, wherein etching the amorphous carbon layer is performed at a temperature of approximately 10° C. to approximately 60° C.; a pressure of approximately 1 mTorr to approximately 100 mTorr; and a ratio of a maximum power to a bias power ranging from approximately 0.5:1 to approximately 1.5:1 in a chamber.

10. The method as recited in claim 1, wherein the hard mask pattern comprises silicon oxynitride (SiON).

11. The method as recited in claim 1, wherein the hard mask pattern is formed by double exposure etching.

12. A method for fabricating a semiconductor device, the method comprising;
forming an amorphous carbon layer over a substrate;
forming a hard mask pattern over the amorphous carbon layer; and
etching the amorphous carbon layer with an etching gas using the hard mask pattern as an etch barrier, wherein the amorphous carbon layer is etched while simultaneously forming a sidewall protection layer on sidewalls of the amorphous carbon layer exposed by the etching.

13. The method as recited in claim 12, wherein the etching gas comprises sulfur (S).

14. The method as recited in claim 13, wherein the etching gas comprises a mixed gas of sulfur dioxide (SO₂) and one selected from the group consisting of carbon monoxide (CO), oxygen (O₂), helium dioxide (HeO₂), nitrogen (N₂) and a combination thereof.

15. The method as recited in claim 13, wherein the etching gas comprises a mixed gas of sulfanylidenemethanone (COS) and one selected from the group consisting of CO, O₂, HeO₂, N₂ and a combination thereof.

16. The method as recited in claim 12, wherein etching the amorphous carbon layer is performed by adding a carbon-hydroxide (CH) based gas or a tetraclorosilane (SiCl₄) gas to the etching gas.

17. The method as recited in claim 12, wherein etching the amorphous carbon layer is performed by adding an argon (Ar) gas to the etching gas.

18. The method as recited in claim 12, wherein etching the amorphous carbon layer is performed by adding a hydrogen bromide (HBr) gas to the etching gas.

19. The method as recited in claim 12, wherein the sidewall protection layer includes carbon sulfide or carbonyl sulfide.

20. The method as recited in claim 12, wherein etching the amorphous carbon layer is performed at a temperature of approximately 10° C. to approximately 60° C.; a pressure of approximately 1 mTorr to approximately 100 mTorr; and a ratio of a maximum power to a bias power ranging from approximately 0.5:1 to approximately 1.5:1 in a chamber.
